(19) United States
(12) Patent Application Publication
(10) Pub. No.: US 2009/0119038 A1
(43) Pub. Date: May 7, 2009

(54) Battery Data Logger And Display

(75) Inventor: Oliver A. Bell, Jr., Aiken, SC (US)

Correspondence Address: HARNESS, DICKEY & PIERCE, P.L.C., P.O. BOX 828, BLOOMFIELD HILLS, MI, 48303, US

(73) Assignee: TEXTRON INC., Providence, RI (US)

(21) Appl. No.: 11/933,628

(22) Filed: Nov. 1, 2007

(51) Int. Cl. G01R 21/06; G06F 19/00

(52) U.S. Cl. 702/62

(57) ABSTRACT

A battery data-logging arrangement for use with an electric vehicle is disclosed. The arrangement includes a first analog-to-digital converter (A2D) that converts a battery voltage signal to battery voltage data. A second A2D converts a battery current signal to battery current data. A clock generates time data. A computer memory is associated with a central processing unit (CPU) that correlates and stores the battery voltage data, the battery current data, and the time data in the memory.

### FIELD OF THE INVENTION

The present invention relates to a method and apparatus for determining accumulated charge flow through a battery.

### BACKGROUND OF THE INVENTION

Electric vehicles generally rely on rechargeable batteries to provide some or all of the energy to propel the vehicle. It is therefore important for engineers to understand interrelationships between battery charge and discharge patterns, battery state of charge, battery age, and battery life expectancy. There remains a need in the art for a simple and economical method to gather and/or generate such data.

### SUMMARY OF THE INVENTION

A battery data-logging arrangement for use with an electric vehicle is disclosed. The arrangement includes a first analog-to-digital converter (A2D) that converts a battery voltage signal to battery voltage data. A second A2D converts a battery current signal to battery current data. A clock generates time data. A computer memory is associated with a central processing unit (CPU) that correlates and stores the battery voltage data, the battery current data, and the time data in the memory.

In other features the memory includes a circular buffer. A first communication port can communicate battery recharge data with the CPU. The time data can include date data. A second communication port can communicate the data stored in the computer memory to an external display. The external display can include a liquid crystal display (LCD) panel. The battery current data can include a magnitude and polarity indicated by the battery current signal.

A method for logging battery data is disclosed. The method includes converting a battery voltage signal to battery voltage data, converting a battery current signal to battery current data, and generating time data. The method correlates and stores the battery voltage data, the battery current data, and the time data.

In other features the storing step includes overwriting the oldest battery voltage data, battery current data, and time data with the newest battery voltage data, battery current data, and time data. The storing step can be performed upon receiving a battery recharge indication. The time data can include date data. The method can also include displaying at least a portion of the battery voltage data, battery current data, and time data. The battery current data can include a magnitude and polarity indicated by the battery current signal. An electric utility vehicle is disclosed that includes a battery, an alternating current (AC) motor controller that converts a direct current (DC) from the battery to a three-phase signal, a three-phase AC motor that converts the three-phase signal to a mechanical torque, and a battery data logging arrangement. The battery data logging arrangement includes a first analog-to-digital converter (A2D) that generates battery voltage data based on a battery voltage signal generated by the battery, a battery current sensor that generates a battery current signal based on the DC battery current, a second A2D that converts the battery current signal to battery current data, a clock that generates time data, and computer memory with an associated central processing unit (CPU) that correlates and stores the battery voltage data, the battery current data, and the time data in the memory.

In other features the memory includes a circular buffer. The battery data logging arrangement can further include a first communication port that communicates with the AC motor controller. The time data can include date data. A second communication port can communicate the data stored in the computer memory to an external display. The external display can include a liquid crystal display (LCD) panel. The battery current data can include a magnitude and polarity indicated by the battery current signal.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a functional block diagram of a battery data logger connected to a vehicle battery;

FIG. 2 is a look-up table of battery current magnitude as a function of a corrected sensor voltage;

FIG. 3 is a flow chart of a method for reading a battery current sensor; and

FIG. 4 is a memory map of the battery data logger.

### DETAILED DESCRIPTION OF THE PREFERRED EMBODIMENTS

The following description of various embodiments is merely exemplary in nature and is in no way intended to limit the present teachings, application, or uses. Throughout this specification, like reference numerals will refer to similar elements.

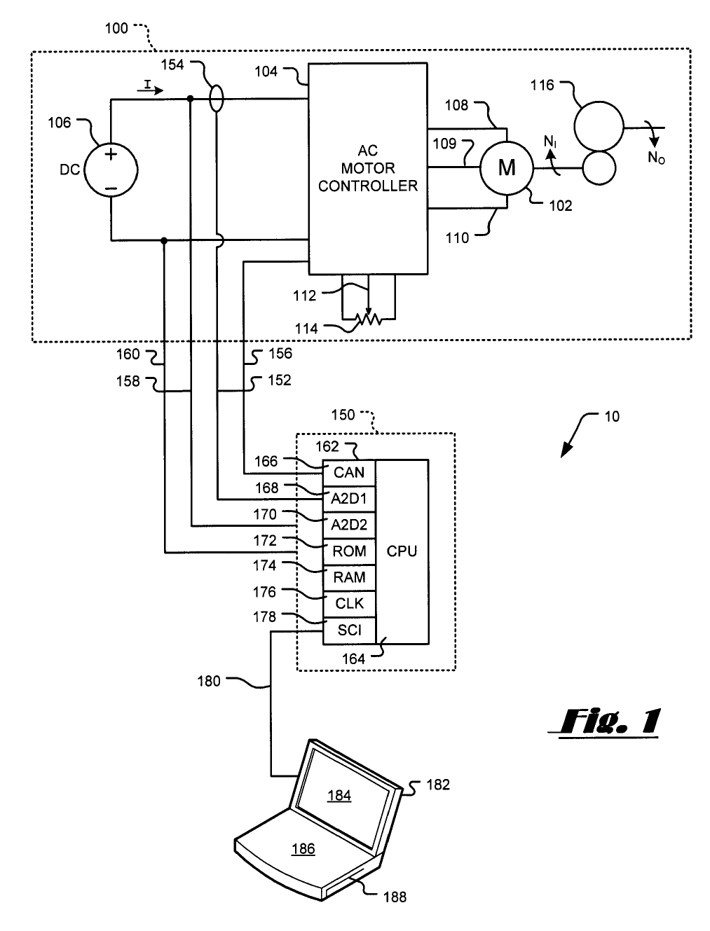

FIG. 1 shows a functional block diagram of one of various embodiments of a battery data logging arrangement 10. The battery data logging arrangement can be used in an engineering environment to determine state-of-charge (SoC) of a vehicle battery over time and/or to correlate environmental variables with their effect on the SoC and/or battery life. In other applications battery data logging arrangement 10 can be used to forecast the useful life of the battery by applying the environmental variables of a particular battery over its service life. This can help reduce unexpected downtime of the vehicle associated with the battery.

A vehicle 100 is an electric-powered vehicle that includes an AC motor 102. An AC motor controller 104 controls motor 102. A rechargeable battery 106 provides a DC battery current I to AC motor controller 104. AC motor controller 104 converts the battery current I to an AC signal and applies it to motor 102 via 3-phase outputs 108, 109, and 110. The AC signal drives motor 102 at a speed that is determined by a pedal position signal 112, which can be generated by a potentiometer 114 that is associated with an accelerator pedal (not shown) of vehicle 100. An output shaft of motor 102 rotates at a first rpm N_{I} that is input to a gear reduction box 116. An output of gear reduction box 116 rotates at a speed Nₒ and provides an output torque for propelling vehicle 100.

A battery data logger 150 receives a current signal 152 from a current sensor 154. Current sensor 154 generates current signal 152 according to a magnitude and direction of the battery current I. Battery data logger 150 can also communicate with AC motor controller 104 via a communication link 156. Communication link 156 can include a controller area network (CAN), a serial communication link, and/or a parallel communication link. Battery data logger 150 can also measure the voltage of battery 106 via a positive battery lead 158 and a negative battery lead 160. Data communicated via communication link 156 can include information related to battery 106 being recharged by an external battery charger (not shown).

A microcontroller unit (MCU) 162 includes a central processing unit (CPU) 164 and various other peripheral modules. Examples of peripheral modules include a CAN communication module 166, a first analog-to-digital converter (A2D) 168, a second A2D 170, a read-only memory (ROM) 172, a random access memory (RAM) 174, a clock 176, and a serial communication interface (SCI) 178. CAN communication module 166 communicates with communication link 156. First A2D 168 receives current signal 152 and converts it to a digital value that CPU 164 processes according to a method that is described below. Second A2D 170 converts the battery voltage to a digital value that CPU 164 also processes. The battery voltage may be scaled, such as by a resistor voltage divider, to match input specifications of second A2D 170.

ROM 172 stores computer software for executing methods described below. CPU 164 can also write to ROM 172 to store voltage and current data related to battery 106. In some embodiments, ROM 172 can include E² PROM or flash memory. RAM 174 provides storage for variables of the methods. Clock 176 provides date and/or time of day information to CPU 164.

SCI 178 provides a connection for a communication link 180 to an external display device 182, such as a laptop, scan tool, in-dash display, and/or other such devices for displaying data. Display device 182 can include a LCD screen 184 and/or other visual displays such as LED's and/or CRT'S. Display device 182 can also include an input device such as a keyboard 186, and/or a digital media reader 188 such as a disk drive, flash card reader, wireless network, etc.

Referring now to FIG. 2, one of various embodiments of a look-up table 200 is shown. Look-up table 200 provides a conversion between a modified voltage of current signal 152 and an absolute value of battery current I. A horizontal axis 202 indicates the modified voltage, which is calculated according to a method described below. A vertical axis 204 indicates the absolute value of battery current I. A dashed line 206 shows that in one embodiment a modified voltage of zero corresponds to a battery current of zero and a modified voltage of 2.5 volts corresponds to an absolute battery current of 200 amps.

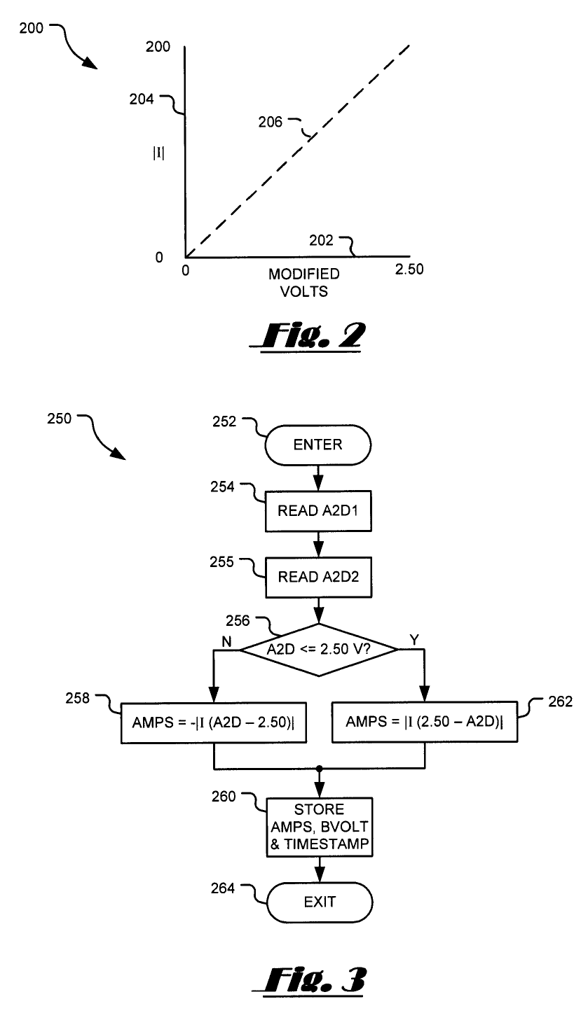

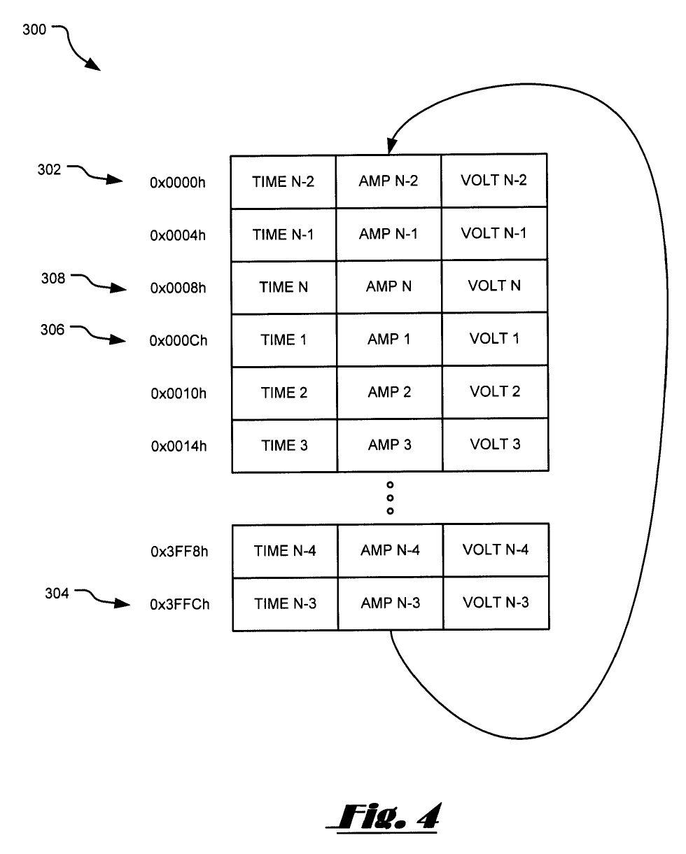

Referring now to FIG. 3, a method 250 is shown for determining the modified voltage. Method 250 also stores battery voltage readings and current readings in ROM 172. Method 250 is stored in a portion of ROM 172 and executed by CPU 164. In some embodiments method 250 is executed each time battery 106 is recharged. Method 250 begins in block 252 and immediately proceeds to block 254 and reads first A2D 168, which indicates the battery current I. Control then proceeds to block 255 and reads second A2D 170, which indicates the battery voltage. Control then proceeds to decision block 256 and determines whether the reading from first A2D 168 is less than or equal to a predetermined value, such as 2.5 volts. The predetermined value is generally selected to correspond to the middle of the possible high and low readings of first A2D 168. If the result in decision block 256 is affirmative, then the battery current I is regenerating charge in battery 106. Control branches to block 258 and subtracts the predetermined value from the reading to arrive at the modified voltage. Control then uses the modified voltage and table 200 to look up the magnitude of regenerative battery current I.

If the result is negative in decision block 256, then the battery current I is motoring current that discharges battery 106. Control branches to block 262 and subtracts the reading from the predetermined value to arrive at the modified voltage. Control then uses the modified voltage and table 200 to look up the magnitude of motoring battery current I. Control arrives at block 260 from blocks 258 and 262. In block 260 control stores the battery current I and the battery voltage together with a time stamp that is read from clock 176. The stored battery current I includes an indication of whether the battery current I is regenerative or motoring. Control then exits at block 264.

Referring now to FIG. 4, one of several embodiments of a memory map 300 is shown. Method 250 can use memory map 300 to organize the stored readings of battery current I, battery voltage, and time stamps. Memory map 300 begins at an offset address 302 and ends at an offset address 304. In some embodiments the size of memory map 300 is 4000 h bytes. Method 250 stores the readings in memory map 300 in a circular buffer fashion. For example, row 306 contains the oldest set of readings. Row 308 contains the newest set of readings and precedes row 306 in memory map 300. Each time method 250 executes it writes the newest readings to the next lower row until reaching the end of memory map 300. Method 250 then continues by writing the newest reading in the first row 302 of memory map 300 and successively writing each new set of readings on a next lower row. This process continues with the most recent readings continuously overwriting the oldest readings.

The motoring and regenerative amp-hours of battery 106 can be calculated based on the stored time stamps and battery current I readings. Also, the amp-hours removed (or added) from battery 106 can be determined based on the motoring and regenerative amp-hours. The watt-hours provided by battery 106 can be determined based on the motoring and regenerative amp-hours combined with the battery voltage readings. All of these determined values can be used to determine the SoC of battery 106 and/or to correlate environmental variables with their effect on the SoC and/or battery life. In other applications the determined values can be used to forecast the useful life of battery 106.

The description herein is merely exemplary in nature and, thus, variations that do not depart from the gist of that which is described are intended to be within the scope of the teachings. Such variations are not to be regarded as a departure from the spirit and scope of the teachings.

What is claimed is:

1. A battery data-logging arrangement for use with an electric vehicle, comprising:
a first analog-to-digital converter (A2D) that converts a battery voltage signal to battery voltage data;
a second A2D that converts a battery current signal to battery current data;
a clock that generates time data; and
computer memory with an associated central processing unit (CPU) that correlates and stores the battery voltage data, the battery current data, and the time data in the memory.

2. The battery data logging arrangement of claim 1 wherein the memory includes a circular buffer.

3. The battery data logging arrangement of claim 1 further comprising a first communication port that communicates battery recharge data with the CPU.

4. The battery data logging arrangement of claim 1 wherein the time data includes date data.

5. The battery data logging arrangement of claim 1 further comprising a second communication port that communicates the data stored in the computer memory to an external display.

6. The battery data logging arrangement of claim 5 wherein the external display includes a liquid crystal display (LCD) panel.

7. The battery data logging arrangement of claim 1 wherein the battery current data includes a magnitude and polarity indicated by the battery current signal.

8. A method for logging battery data, comprising:
converting a battery voltage signal to battery voltage data;
converting a battery current signal to battery current data;
generating time data;
correlating the battery voltage data, the battery current data, and the time data; and
storing the battery voltage data, the battery current data, and the time data.

9. The method of claim 8 wherein the storing step includes overwriting the oldest battery voltage data, battery current data, and time data with the newest battery voltage data, battery current data, and time data.

10. The method of claim 8 further comprising performing the storing step upon receiving a battery recharge indication.

11. The method of claim 8 wherein the time data includes date data.

12. The method of claim 8 further comprising displaying at least a portion of the battery voltage data, battery current data, and time data.

13. The method of claim 8 wherein the battery current data includes a magnitude and polarity indicated by the battery current signal.

14. An electric utility vehicle, comprising:
a battery;
an alternating current (AC) motor controller that converts a direct current (DC) from the battery to a three-phase signal;
a three-phase AC motor that converts the three-phase signal to a mechanical torque; and
a battery data logging arrangement comprising
a first analog-to-digital converter (A2D) that generates battery voltage data based on a battery voltage signal generated by the battery;
a battery current sensor that generates a battery current signal based on the DC battery current;
a second A2D that converts the battery current signal to battery current data;
a clock that generates time data; and
computer memory with an associated central processing unit (CPU) that correlates and stores the battery voltage data, the battery current data, and the time data in the memory.

15. The vehicle of claim 14 wherein the memory includes a circular buffer.

16. The vehicle of claim 14 wherein the battery data logging arrangement further includes a first communication port that communicates with the AC motor controller.

17. The vehicle of claim 14 wherein the time data includes date data.

18. The vehicle of claim 14 further comprising a second communication port that communicates the data stored in the computer memory to an external display.

19. The vehicle of claim 18 wherein the external display includes a liquid crystal display (LCD) panel.

20. The vehicle of claim 14 wherein the battery current data includes a magnitude and polarity indicated by the battery current signal.
